(19) United States
(12) Patent Application Publication
(10) Pub. No.: US 2025/0339932 A1
(43) Pub. Date: Nov. 6, 2025

(54) CONDITIONING PAD WITH DEPOSITED DIAMOND COATING

(71) Applicant: Taiwan Semiconductor Manufacturing Company, Ltd., Hsinchu (TW)

(72) Inventors: Te-Chien Hou, Kaohsiung (TW); Chi-hsiang Shen, Tainan (TW); Jeng-Chi Lin, Hsinchu (TW); Chen-Hsueh Lin, Kaohsiung (TW); Shich-Chang Suen, Hsinchu (TW)

(73) Assignee: Taiwan Semiconductor Manufacturing Company, Ltd., Hsinchu (TW)

(21) Appl. No.: 18/654,400

(22) Filed: May 3, 2024

(51) Int. Cl. B24B 37/24; H01L 21/306

(52) U.S. Cl. CPC B24B 37/24; H01L 21/30625

(57) ABSTRACT

Pads, methods for manufacturing conditioning pads, and methods for polishing are provided. A pad for use in semiconductor fabrication includes a base member having an upper surface; projections extending upward from the upper surface of the base member, wherein the projections are formed with an edge defined by at least two intersecting surfaces; and a diamond layer overlying the projections.

### BACKGROUND

Semiconductor or integrated circuit (IC) devices are constructed using complex fabrication processes that form a plurality of different layers on top of one another. Many of the layers are patterned using photolithography, in which a light sensitive photoresist material is selectively exposed to light. For example, photolithography is used to define back-end metallization layers that are formed on top of one another. To ensure that the metallization layers are formed with a good structural definition, the patterned light must be properly focused. To properly focus the pattered light, a workpiece must be substantially planar to avoid depth of focus problems.

Chemical mechanical polishing (CMP) is a widely used process by which both chemical and mechanical forces are used to globally planarize a semiconductor workpiece. The planarization prepares the workpiece for the formation of a subsequent layer. A typical CMP tool comprises a rotating platen covered by a polishing pad. A slurry distribution system is configured to provide a polishing mixture, having chemical and abrasive components, to the polishing pad. A workpiece is then brought into contact with the rotating polishing pad to planarize the workpiece. CMP is a favored process because it achieves global planarization across the entire wafer surface. The CMP process polishes and removes materials from the wafer, and works on multi-material surfaces. Furthermore, the CMP process avoids the use of hazardous gases, and/or is usually a low-cost process.

### BRIEF DESCRIPTION OF THE DRAWINGS

Aspects of the present disclosure are best understood from the following detailed description when read with the accompanying figures. It should be noted that, in accordance with the standard practice in the industry, various features may not be drawn to scale. In fact, the dimensions of the various features may be arbitrarily increased or reduced for clarity of discussion.

FIG. 1 is a schematic view of a Chemical Mechanical Polishing (CMP) tool in accordance with some embodiments.

FIG. 2 is a perspective view of a polishing location in the CMP tool of FIG. 1 in accordance with some embodiments.

FIGS. 3-4 are cross-sectional schematic views illustrating formation of the conditioning pad of FIG. 2 in accordance with some embodiments.

FIGS. 5-6 are cross-sectional schematic views illustrating formation of the conditioning pad of FIG. 2 in accordance with some embodiments.

FIG. 7 is a cross-sectional schematic view illustrating formation of the conditioning pad of FIG. 2 in accordance with some embodiments.

FIG. 8 is a cross-sectional schematic view illustrating formation of the conditioning pad of FIG. 2 in accordance with some embodiments.

FIG. 9 is a cross-sectional schematic view illustrating formation of the conditioning pad of FIG. 2 in accordance with some embodiments.

FIGS. 10-15 are overhead views of the conditioning surface of the conditioning pad of FIG. 2 in accordance with some embodiments.

FIG. 16 is a flow chart illustrating a method in accordance with some embodiments.

FIG. 17 is an overhead view of projections formed in FIG. 3 in accordance with some embodiments.

FIG. 18 is an overhead view of first projections and second projections formed over a base member according to FIG. 8 in accordance with some embodiments.

FIG. 19 is an overhead view of first projections, second projections, and third projections formed over a base member according to FIG. 9 in accordance with some embodiments.

FIG. 20 is a perspective view, and FIG. 21 is a cross-sectional view, of a semiconductor structure at a stage of fabrication in accordance with some embodiments.

FIG. 22 is a perspective view, and FIG. 23 is a cross-sectional view, of the semiconductor structure of FIGS. 20-21 at a next stage of fabrication in accordance with some embodiments.

FIG. 24 is a perspective view, and FIG. 25 is a cross-sectional view, of the semiconductor structure of FIGS. 22-23 at a next stage of fabrication in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In addition, the present disclosure may repeat reference numerals and/or letters in the various examples. This repetition is for the purpose of simplicity and clarity and does not in itself dictate a relationship between the various embodiments and/or configurations discussed.

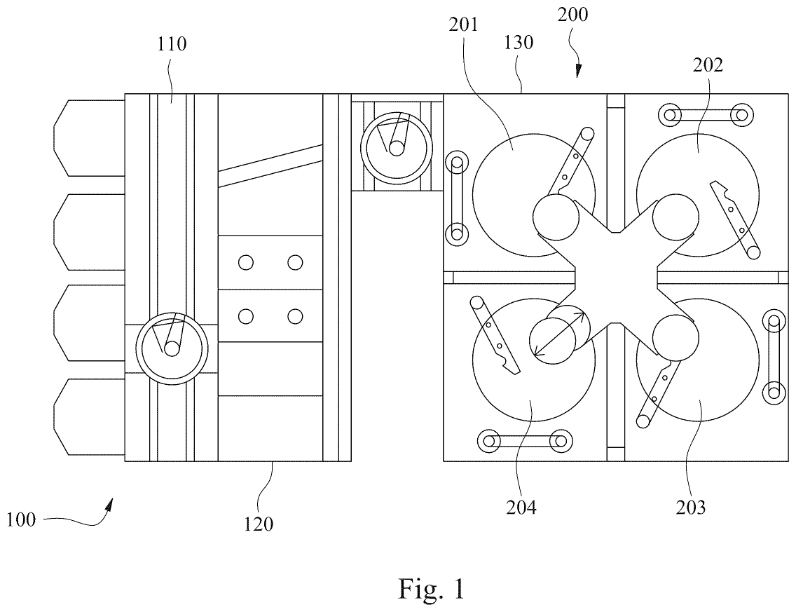

FIG. 1 is a schematic view of a Chemical Mechanical Polishing (CMP) device or tool 100. The tool 100 is configured for performing a Chemical Mechanical Polishing (CMP) process on a wafer in a semiconductor manufacturing process. The Chemical Mechanical Polishing (CMP) tool 100 may include a wafer transportation unit 110, a cleaning unit 120, and a polishing unit 130. Typically, the wafer transportation unit 110 transports a wafer to the polishing unit 130, where the wafer is polished. Thereafter, the wafer transportation unit 110 transports the wafer to the cleaning unit 120, wherein the wafer is cleaned.

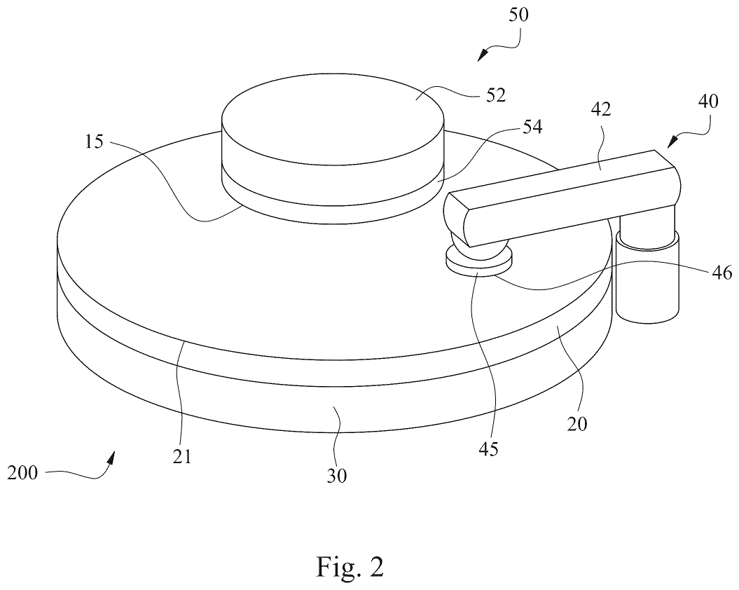

As shown, a polishing unit 130 may include four polish locations or modules 200 where the unit 130 may perform a Chemical Mechanical Polishing (CMP) operation on a wafer. For example, the polishing module 200 may include a first main polishing module 201, a second main polishing module 202, a first chemical buff module 203, and a second chemical buff module 204. In certain embodiments, during operation of the polishing tool 100, a wafer may be processed in succession by each module 200. In certain embodiments, during operation of the polishing tool 100, a first wafer may be processed by the first main polishing module 201 and then by the first chemical buff module 203 while a second wafer may be processed by the second main polishing module 202, and then by the second chemical buff module 204. While FIG. 2 illustrates four polishing modules 200, any suitable number of polishing modules 200 may be employed.

FIG. 2 is a schematic view of a Chemical Mechanical Polishing (CMP) polishing module 200. The module 200 is configured for performing a Chemical Mechanical Polishing (CMP) process on a wafer 15 in a semiconductor manufacturing process. As shown, the module 200 includes a polishing pad 20, a platen 30, a pad conditioner assembly 40, and a wafer holder assembly 50, in accordance with some embodiments. The elements of the polishing module 200 can be added to or omitted, and the disclosure should not be limited by the embodiments.

The platen 30 is configured to receive and rotate the polishing pad 20 about a central pad rotation axis. In some embodiments, the platen 30 is circular in shape. The diameter of the platen 30 lies in a range that is substantially larger than the diameter of a wafer 15 to be polished. A platen motor (not shown) rotates the platen 30 about an axis. The platen motor may be electrically connected to a control module in the Chemical Mechanical Polishing (CMP) tool and may be actuated and operated by the control module.

In an embodiment, the polishing pad 20 is fixed onto the platen 30. The polishing pad 20 may be a consumable item used in a semiconductor wafer fabrication process. A polishing pad 20 may be a hard, incompressible pad or a soft pad. For oxide polishing, hard and stiffer pads are generally used to achieve planarity. Softer pads are generally used in other polishing processes to achieve improved uniformity and a smooth surface. Hard pad and soft pad components may also be combined in an arrangement for customized applications.

In certain embodiments, the polishing pad 20 may be formed by three-dimensional printing with desired portions formed from a material having a higher thermal conductivity and desired portions formed from material having a lower thermal conductivity, or formed with other desired attributes.

The wafer holder assembly 50 is used to support the wafer 15. In some embodiments, the wafer holder assembly 50 may include a shaft with a driving motor (not shown), a carrier head 52, and a retention ring 54. The driving motor may be configured to control rotational movement of the carrier head 52 and retention ring 54 about a wafer rotation axis. The wafer rotation axis is different from the pad rotation axis. In some embodiments, the driving motor is an electric motor which converts electrical energy into mechanical energy for driving the rotation of the carrier head 52 and retention ring 54. In some embodiments, the carrier head 52 and retention ring 54 are driven to rotate about the wafer rotation axis by an external force (e.g., frictional force generated between the polishing pad 20 and the wafer 15).

The pad conditioner 40 can be configured to condition polishing pad 20 (e.g., roughen and texturize the surface of polishing pad 20). As illustrated, the pad conditioner 40 includes a conditioning pad or disk 45 mounted on a conditioning arm 42, according to some embodiments of the present disclosure.

In some embodiments, the conditioning arm 42 can be extended over the top of polishing pad 20 to sweep (e.g., in an arc motion) across the entire surface of polishing pad 20. As platen 30 rotates, different areas of polishing pad 20 can be fed under wafer 15 and used to polish the substrate. In some embodiments, platen 30 moves areas of polishing pad 20 that were previously in contact with wafer 15 to pad conditioner 40. The conditioning arm 42 sweeps pad conditioner 40 across the areas previously used to polish wafer 15 and conditions these areas. Platen 30 then moves these areas back under wafer holder assembly 50 and wafer 15. In this manner, polishing pad 20 can be conditioned, e.g., simultaneously conditioned, while wafer 15 is polished.

Conditioning pad 45 can have different compositions as described below. Conditioning pad 45 can be used to roughen and condition a polishing surface 21 of polishing pad 20. Due to the conditioning by conditioning pad 45, the surface 21 of polishing pad 20 is refreshed and the polishing rate can be maintained. The pad conditioning process can be carried out either during a polishing process, i.e. known as concurrent conditioning, or after the polishing process.

Traditional Chemical Mechanical Polishing (CMP) conditioning pads may have rough protrusions that create undesirably high roughness texture of the polishing pad 20. Differences in polishing pad roughness may lead to a variation in removal rate during polishing. Thus, it is desirable to precisely control the surface topography of the conditioning pad so that the polishing pad may be properly conditioned.

Embodiments herein involve chemical mechanical polishing (CMP) processes and Chemical Mechanical Polishing (CMP) tools such as the tool of FIGS. 1 and 2. Chemical Mechanical Polishing (CMP) is a method of planarizing or flattening out a semiconductor wafer surface by polishing away a thin layer of wafer surface. Traditionally, CMP polishing pads include a single material and are formed by a molding fabrication process. CMP polishing pads may lose a desired polishing effect and need to be conditioned such as by the conditioning pad 45.

Embodiments herein achieve better within wafer “WiW” thickness uniformity control of wafers and mitigate CMP-induced defects during polishing, by conditioning the polishing pad with conditioning pads having improved topography. Such topography may result from controlled formation of projections and/or controlled placement of projections according to layout designs optimized for polishing pad surface texture control.

Through improved conditioning pad topography, embodiments herein may improve within die “WiD” loading, reduce dishing, and reduce erosion. Further, embodiments herein may provide for healthier down force settings, an increase in within wafer thickness uniformity, improved wafer to wafer “WtW” uniformity, reduction in CMP-induced defectivity (fall-on, scratch). With more uniform within wafer thickness and fewer defects on wafers, chip yield and IC device performance will be sharply improved.

As semiconductor technology node advances to five nanometers and beyond, standards for within wafer, within die, and wafer to wafer uniformity are increasingly stringent. For example, poor thickness uniformity across a wafer can lead to pattern failure, thus impacting chip yield and electrical characteristics.

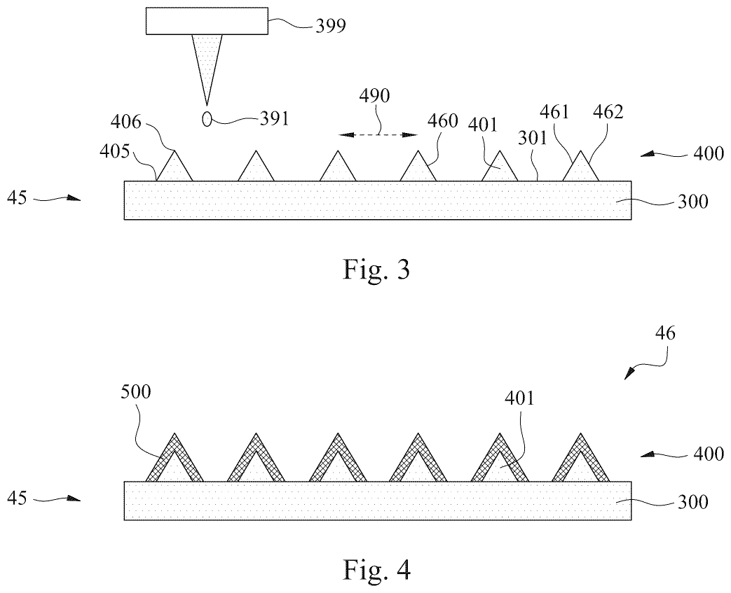

FIGS. 3-4 illustrate the formation of a conditioning pad 45 according to some embodiments. In FIG. 3 an additive manufacturing device or three-dimensional printer 399 forms a base member 300 of the conditioning pad 45 from a first material 391. As shown, the base member 300 has an upper surface 301. Grains or pixels of the first material 391 are fused together during a three-dimensional printing process. Through use of three-dimensional printing, the hardness and other properties of the conditioning pad 45 may be controlled at a pixel level. Specifically each grain or material fraction can be manufactured by three-dimensional printing technology providing for pixel-level precision control. Each grain or pixel may be formed from acrylic, polyurethane (PU), polyester, polyimide, carbon treated polymer, and/or combinations thereof. Further, the three-dimensional printer 399 forms an array of projections 400 at a same pitch 490. In certain embodiments, the pitch 490 is from fifty (50) to 2000 micrometers (μm). For example, the pitch 490 may be at least 50, at least 60, at least 70, at least 80, at least 90, at least 100, at least 120, at least 140, at least 160, at least 180, at least 200, at least 250, at least 300, at least 350, at least 400, at least 450, at least 500, at least 600, at least 700, at least 800, at least 900, at least 1000, at least 1250, at least 1500, or at least 1750 um. Further, the pitch 490 may be at most 55, at most 60, at most 70, at most 80, at most 90, at most 100, at most 120, at most 140, at most 160, at most 180, at most 200, at most 250, at most 300, at most 350, at most 400, at most 450, at most 500 um, at most 600, at most 700, at most 800, at most 900, at most 1000, at most 1250, at most 1500, at most 1750, or at most 2000 μm.

In the embodiment of FIG. 3, the projections 400, which may be considered to be first projections 401, are formed from a common material. For example, the projections 400 may be formed from acrylic, polyurethane (PU), polyester, polyimide, carbon treated polymer, and/or combinations thereof. For example, the projections may be a combination of acrylic and carbon treated polymer, a combination of polyurethane and carbon treated polymer, a combination of polyester and carbon treated polymer, or a combination of polyimide and carbon treated polymer. In the embodiment of FIG. 3, the projections 401 are formed from the same material 391 as the base member 300.

In certain embodiments, the projections 400 have a base 405 and an apex 406. As shown, the base 405 of each projection 400 contacts the upper surface 301 of the base member 300 and each projection 400 extends away from the base member 300 to the apex 406. In certain embodiments, each projection 400 has a maximum width at the base 405. Further, the width of each projection may decrease along a height moving upward from the base 405 to the apex 406, where the projection 400 terminates. In certain embodiments, the apex 406 is a point, through in other embodiments, the apex 406 may be linear or planar. In the illustrated embodiment, the width of each projection 400 decreases at a constant rate from the base 405 to the apex 406. In other embodiments, the width of each projection 400 decrease intermittently.

In certain embodiments, the projections 400 are formed with a triangular cross-sectional shape, as shown in FIG. 3. Thus, each projection 400 may have a pyramidal or conical shape. For example, a projection 400 may have a triangular pyramid shape, a rectangular pyramid shape, a hexagonal pyramid shape, another pyramid shape, or a conical shape. In certain embodiments, each projection 400 may be truncated.

The projections 400 may be formed with a selected number of sides 460. For example, in FIG. 3, the projections 400 have two sides 460 including a first side 461 and a second side 462. As shown, the two sides 461 and 462 converge toward one another from the upper surface 301 of the base member 300.

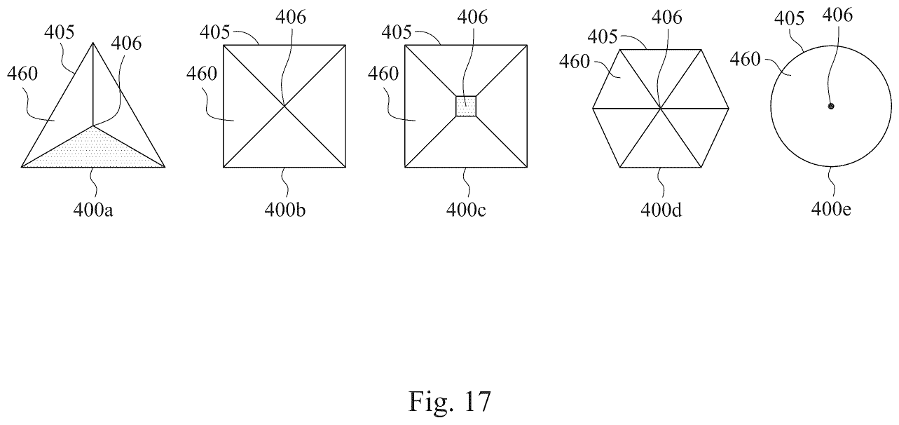

Referring to FIG. 17, overhead views of various embodiments of projections 400 are shown. For example, projection 400a has a triangular pyramid shape, with three sides 460, a triangular base 405, and an point apex 406; projection 400b has a rectangular pyramid shape, with four sides 460, a rectangular (or square) base 405, and an point apex 406; projection 400c has a truncated rectangular pyramid shape, with four sides, a rectangular (or square) base 405 and a flat surface apex 406 having the same shape as the base 405; projection 400d has a hexagonal pyramid shape, with six sides 460, a hexagonal base 405, and an point apex 406; and projection 400e has a round conical shape, with one side 460, a round (or circular) base 405, and an point apex 406. In each embodiment, opposite surfaces, whether formed by different sides of a multi-sided embodiment or by a same side 460 of a round embodiment, converge from the base 405 to the apex 406. While projections 400a-400e present certain shapes, they are not limiting and other shapes are envisioned. Further, any of the shapes may be truncated such that the apex 406 is formed as a flat surface apex rather than a point.

In FIG. 4, a diamond layer 500 is formed over the projections 401. The diamond layer 500 may be a Chemical Vapor Deposition (CVD) diamond layer 500. For example, the diamond layer 500 may be formed from decomposing a mixture of carbon-containing gas (such as methane) and hydrogen under high temperature and below standard atmosphere pressure to form plasma carbon atoms, which are deposited on the projections and grow into polycrystalline diamond (or single crystal or quasi single crystal by controlling the deposition growth conditions). Because CVD diamond does not contain any metallic and nonmetallic bonds, most of its properties are similar or identical to single crystal diamonds.

As a result of forming the diamond layer 500 over the projections 401, formation of the conditioning pad 45 may be completed, with the conditioning surface 46 having a desired roughness.

In certain embodiments, the diamond layer 500 has a thickness of from 1 to 500 micrometers (μm). For example, the diamond layer 500 may have a thickness of at least 1, at least 2, at least 3, at least 4, at least 5, at least 10, at least 20, at least 30, at least 40, at least 50, at least 60, at least 70, at least 80, at least 90, at least 100, at least 120, at least 140, at least 160, at least 180, at least 200, at least 250, at least 300, at least 350, at least 400, or at least 450 um. Further, the diamond layer 500 may have a thickness of at most 15, at most 20, at most 30, at most 40, at most 50, at most 60, at most 70, at most 80, at most 90, at most 100, at most 120, at most 140, at most 160, at most 180, at most 200, at most 250, at most 300, at most 350, at most 400, at most 450, or at most 500 μm.

In certain embodiments, the diamond layer coated projections 400 have a height of from 10 to 500 micrometers (μm). For example, the diamond layer 500 may have a height of at least 10, at least 20, at least 30, at least 40, at least 50, at least 60, at least 70, at least 80, at least 90, at least 100, at least 120, at least 140, at least 160, at least 180, at least 200, at least 250, at least 300, at least 350, at least 400, or at least 450 um. Further, the diamond layer 500 may have a height of at most 15, at most 20, at most 30, at most 40, at most 50, at most 60, at most 70, at most 80, at most 90, at most 100, at most 120, at most 140, at most 160, at most 180, at most 200, at most 250, at most 300, at most 350, at most 400, at most 450, or at most 500 μm.

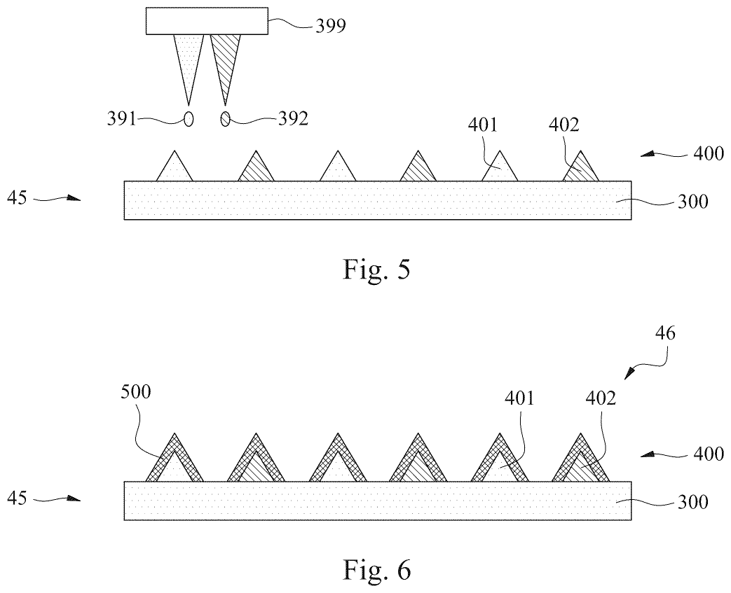

FIGS. 5-6 illustrate another embodiment for forming a conditioning pad 45. In FIG. 5 an additive manufacturing device or three-dimensional printer 399 again forms a base member 300 of the conditioning pad 45 from a first material 391. Further, the three-dimensional printer 399 forms an array of first projections 401 from the first material 391. Also, the three-dimensional printer 399 forms an array of second projections 402 from a second material 402. In some embodiments, the first material 391 and second material 392 have a different hardness, such that the first projections 401 are harder than the second projections 402. The hardness of the material or projections may refer to Mohs hardness, Brinell hardness, and/or Vickers hardness.

It is noted that the first material and second material may be selected from acrylic, polyurethane (PU), polyester, polyimide, carbon treated polymer, and/or combinations thereof. In other embodiments, other materials suitable for three-dimensional printing and for use in the conditioning pad may be used.

While FIG. 5 illustrates the first projections 401 and second projections 402 as being arranged with a same pitch and alternating, other layouts are contemplated. For example, any desired arrangement of first projections 401 and second projections 402 may be utilized.

In FIG. 6, a diamond layer 500 is formed over the projections 401 and the projections 402. The diamond layer 500 may be a Chemical Vapor Deposition (CVD) diamond layer 500. For example, the diamond layer 500 may be formed from decomposing a mixture of carbon-containing gas (such as methane) and hydrogen under high temperature and below standard atmosphere pressure to form plasma carbon atoms, which are deposited on the projections and grow into polycrystalline diamond (or single crystal or quasi single crystal by controlling the deposition growth conditions). Because CVD diamond does not contain any metallic and nonmetallic bonds, most of its properties are similar or identical to single crystal diamonds. In certain embodiments, the diamond layer 500 is formed on the surfaces of the projections 400, and not on the upper surface of the base member 300.

As a result of forming the diamond layer 500 over the projections 401 and the projections 402, formation of the conditioning pad 45 may be completed, with the conditioning surface 46 having a desired roughness.

Comparing the conditioning pad 45 of FIGS. 4 and 6, it may be understood that the roughness of the pad 45 of FIG. 6 may be reduced through the use of the softer second material in second projections 402.

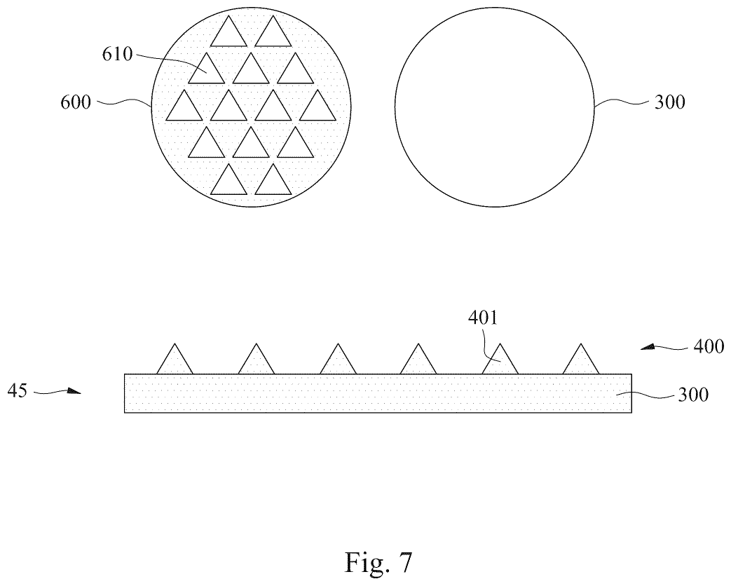

Referring now to FIG. 7, another embodiment for forming a conditioning pad 45 is illustrated. In FIG. 7, a sieve 600 with voids 610 is placed over the base member 300. A material, such as material 391 or 392 or another material, may be located on the base member 300 through the sieve to form projections 401. While a single sieve 600 and only first projections 401 are illustrated in FIG. 7, it is contemplated that more than one sieve may be used to form more than one type of projections, such as for example, first projections 401 and second projections 402. After formation of the projections 401, the projections 401 may be fixed to the base member with binder.

Thus, the structure of FIG. 7 is obtained. Thereafter, the diamond layer may be formed over the projections, such as is shown in FIG. 4.

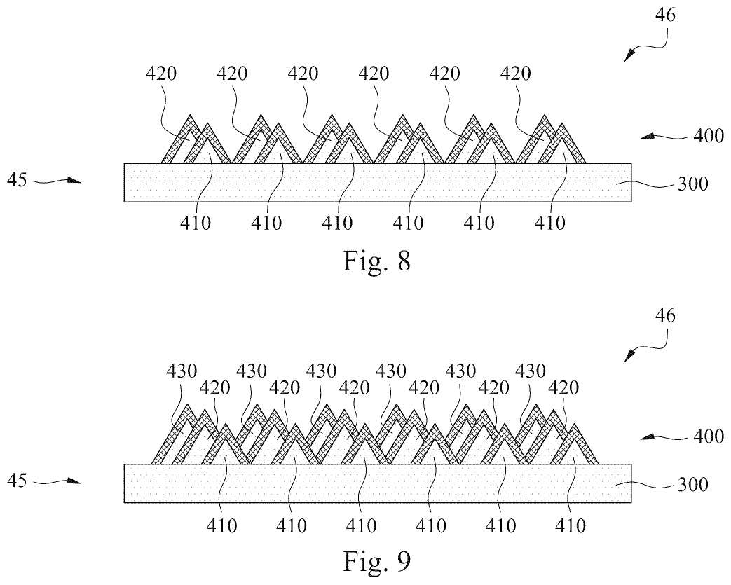

FIG. 8 is a schematic illustrating further processing of a conditioning pad 45. Specifically, the first array of projections 410 (including projections 401 or projections 401 and 402) formed with a first pitch have been formed over the base member 300. Thereafter, a second array of projections 420 are formed over the first array of projections 410. The second array of projections 420 are offset from the first array of projections 410 as shown. It is noted that each projection 420 in FIG. 8 is illustrated in an individual cross-section.

Locating the second projections 420 at a desired distance from the first projections 410 may allow for further tuning of the roughness of the conditioning pad.

Further, each projection 410 of the first array and each projection 420 of the second array may be formed from material of different levels of hardness. Thus, the roughness provided by the conditioning pad 45 of FIG. 8 may be achieved by arranging both the material type of each projection and the offset location and/or density of projections.

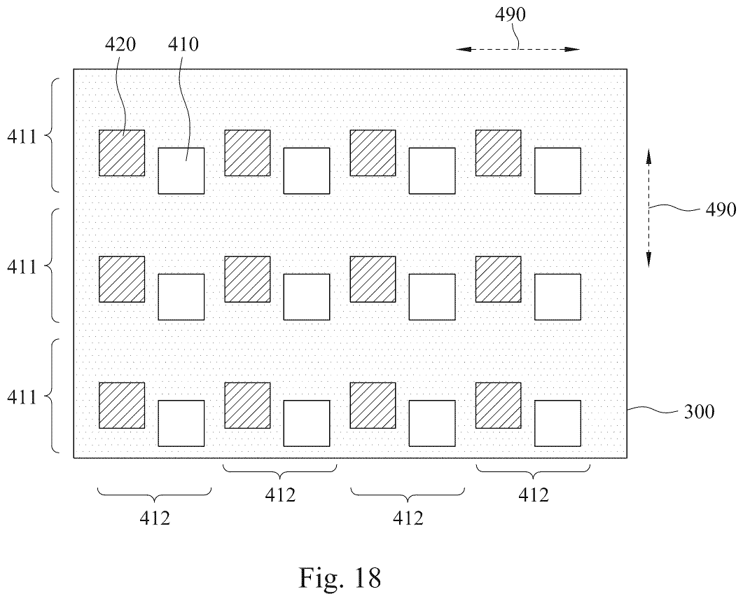

Referring to FIG. 18, an overhead view of the projections 410 and 420 of FIG. 8 is provided over a portion of a base member 300. As shown, first projections 410 are formed with a vertical pitch 490 and horizontal pitch 490 from one another. The first projections 410 may be formed in rows 411 and columns 412. In order to provide the region of the substrate 300 with more densely arranged projections, second projections 420 are formed around the first projections 410. The second projections 420 may be formed with a same or different material as the first projections 410, with a same or different vertical pitch or horizontal pitch, and/or with a same or different projection shape, width, and/or height. In the illustrated embodiment, one first projection 410 and one second projection 420 are formed in each region defined by a single row 411 and single column 412.

In certain embodiments, formation of the conditioning pad 45 of FIG. 8 is complete. In other embodiments, further processing may be performed as shown in FIG. 9.

FIG. 9 illustrates further processing of the conditioning pad 45 of FIG. 8. As shown, a third array of projections 430 are formed over the first array of projections 410 and over the second array of projections 420. As shown, the third array of projections 430 are offset from the first array of projections 410 and the second array of projections 420 as shown.

Locating the third projections 430 at a desired distance from the first projections 410 and second projections 420 may allow for further tuning of the roughness of the conditioning pad.

Further, each projection 410 of the first array, each projection 420 of the second array, and each projection 430 of the third array may be formed from material of different levels of hardness. Thus, the roughness provided by the conditioning pad 45 of FIG. 9 may be achieved by arranging both the material type of each projection and the offset location and/or density of projections.

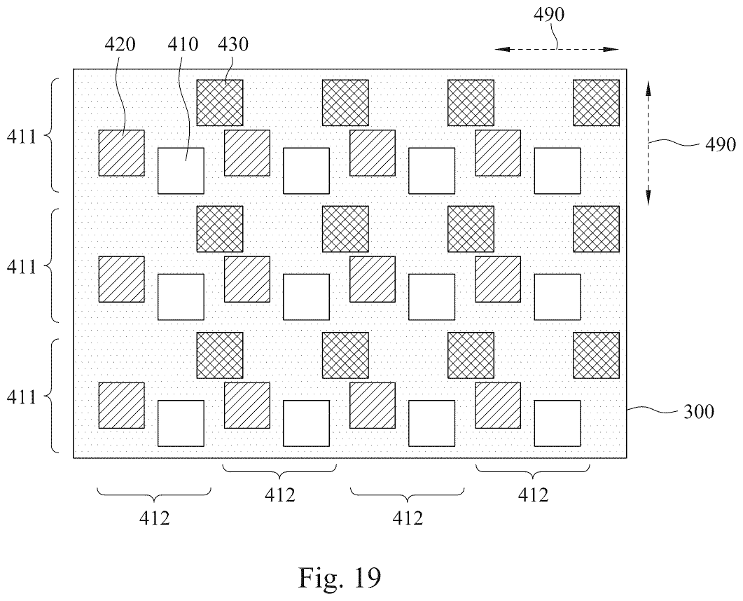

Referring to FIG. 19, an overhead view of the projections 410, 420, and 430 of FIG. 9 is provided over a portion of a base member 300. Further to the embodiment of FIG. 18, and in order to provide the region of the substrate 300 with even more densely arranged projections 400, third projections 430 are formed around second projections 420 and first projections 410. The third projections 430 may be formed with a same or different material as the first projections 410 and/or second projections, with a same or different vertical pitch or horizontal pitch as first and/or second projections, and/or with a same or different projection shape, width, and/or height as first and/or second projections. In the illustrated embodiment, one first projection 410, one second projection 420, and one third projection 430 are formed in each region defined by a single row 411 and single column 412.

As shown in FIGS. 8 and 9, the heights of the first projections 410, second projections, and third projections 430 may differ. For example, the third projections 430 may be taller than the second projections 420, which may be taller than the first projections 410. In other embodiments, projections 410, 420 and 430 are substantially equal.

The formation process of FIGS. 3-6 and/or the formation process of FIG. 7 may be used to form the second array of FIG. 8 and the third array of FIG. 9.

While three-dimensional printing with two different materials are illustrated and described, it is contemplated that three, or more than three different materials may be used to form the base member and projections of the conditioning pad 45.

It is noted that while specific geometric arrangements of the projections 400, including first projections 410, second projections 420, and third projections 430 are illustrated and described, embodiments herein are not so limited. In certain embodiments, the addition of the second projections 420 and third projections 430 to the first projection 410 may provide flexibility in design. For example, printing of the additional projections 420 and 430 may allow for increased density beyond the capability of a single printing process for forming projections 410 at a minimum pitch. Further, using different materials, shapes, widths, and heights of projections 410, 420 and 430 provides the capability of tuning the roughness of a region. For example, projections 410, 420, and/or 430 may be formed in some regions of the conditioning pad and not in other regions. Thus, the density of projections and hardness of projections may be selected and vary region to region.

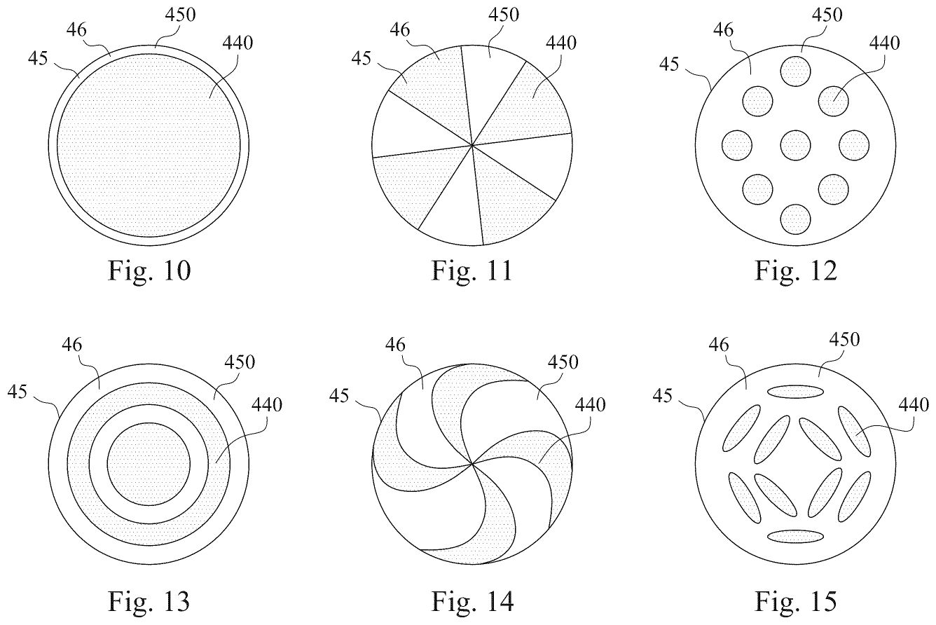

FIGS. 10-15 illustrate different arrangements of diamond layer coated projection regions 440 and regions 450 without diamond layer coated projections on the conditioning surface 46 of the conditioning pad 45.

In FIG. 10, a single round diamond layer coated projection region 440 is provided and is surrounded at its periphery by an annular region 450 without projections.

In FIG. 11, a fan arrangement is provided and includes alternating sectors of diamond layer coated projection regions 440 and regions 450 without diamond layer coated projections.

In FIG. 12, a multiple pellet arrangement is provided and includes circle shaped diamond layer coated projection regions 440 dispersed in a continuous region 450. Alternatively, regions 450 could be dispersed within a continuous region 440.

In FIG. 13, a concentric arrangement is provided and includes radially-alternating diamond layer coated projection regions 440 and regions 450 without diamond layer coated projections.

In FIG. 14, a turbine arrangement is provided and includes alternating turbine or spiral-shaped diamond layer coated projection regions 440 and regions 450 without diamond layer coated projections.

In FIG. 15, a segmented arrangement is provided and includes oval shaped diamond layer coated projection regions 440 dispersed in a continuous region 450. Alternatively, regions 450 could be dispersed within a continuous region 440.

While FIGS. 10-15 illustrate several possible embodiments, other arrangements are contemplated and may be designed to provide desired conditioning effects to the polishing pad.

Cross-referencing FIGS. 3-15, it may be seen that a conditioning pad may be formed with a projection of one hardness (FIG. 4), two hardnesses (FIG. 6), or more than two hardnesses; with a single array of projections (FIG. 4 or 6), with two arrays of projections (FIG. 8), or with three arrays of projections (FIG. 9), and laid out on the conditioning surface according to one of the designs of FIGS. 10-15. For example, such combinations may include: single array/single projection material/round region layout; single array/single projection material/fan region layout; single array/single projection material/multiple pellet region layout; single array/single projection material/concentric region layout; single array/single projection material/turbine region layout; single array/single projection material/segmental region layout; single array/hybrid projection material/round region layout; single array/hybrid projection material/fan region layout; single array/hybrid projection material/multiple pellet region layout; single array/hybrid projection material/concentric region layout; single array/hybrid projection material/turbine region layout; single array/hybrid projection material/segmental region layout; double array/single projection material/round region layout; double array/single projection material/fan region layout; double array/single projection material/multiple pellet region layout; double array/single projection material/concentric region layout; double array/single projection material/turbine region layout; double array/single projection material/segmental region layout; double array/hybrid projection material/round region layout; double array/hybrid projection material/fan region layout; double array/hybrid projection material/multiple pellet region layout; double array/hybrid projection material/concentric region layout; double array/hybrid projection material/turbine region layout; double array/hybrid projection material/segmental region layout; triple array/single projection material/round region layout; triple array/single projection material/fan region layout; triple array/single projection material/multiple pellet region layout; triple array/single projection material/concentric region layout; triple array/single projection material/turbine region layout; triple array/single projection material/segmental region layout; triple array/hybrid projection material/round region layout; triple array/hybrid projection material/fan region layout; triple array/hybrid projection material/multiple pellet region layout; triple array/hybrid projection material/concentric region layout; triple array/hybrid projection material/turbine region layout; and triple array/hybrid projection material/segmental region layout.

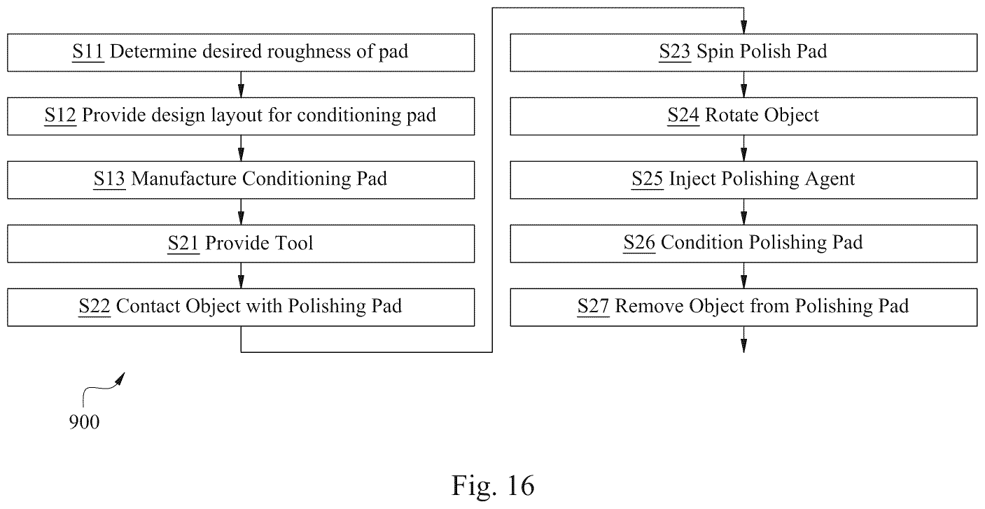

Referring to FIG. 16, a flow chart of a method 900 is illustrated. Cross-referencing FIG. 16 with FIGS. 1-15, method 900 includes, at operation S11, determining a desired roughness of the conditioning pad. For example, the desired roughness may include an overall roughness value, and/or regional roughness values.

At operation S12, method 900 includes providing a design layout to obtain the desired roughness of the conditioning pad. The design layout may include material selection, topography, pitch, number of arrays, and design of regions of diamond layer coated projections. For example, a process module may be used to model a design layout of the conditioning pad. As used herein, the term “process module” refers to any hardware, software, firmware, electronic control unit or component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality. An embodiment of the present disclosure may employ various integrated circuit components, e.g., memory elements, digital signal processing elements, logic elements, look-up tables, or the like, which may conduct a variety of functions under the control of one or more microprocessors or other control devices.

At operation S13, method 900 includes manufacturing the conditioning pad with the design layout, with processes such as described above.

In certain embodiments, manufacturing the conditioning pad with the desired layout includes manufacturing projections from a first material with a first hardness and second projections from a second material with a second hardness less than the first hardness.

In certain embodiments, manufacturing the conditioning pad with the desired layout includes fusing first grains formed from a first material with a first hardness and second grains formed from a second material with a second hardness less than the first hardness in an arrangement.

In certain embodiments, manufacturing the conditioning pad with the desired layout includes performing a process to form a first array of projections, followed by a process to form a second array of projections, and optionally followed by process to form a third array of projections.

Operations S11 through S13 may be considered to represent a method for manufacturing a conditioning pad.

Method 900 may continue at operation S21 with providing a polishing tool 100 including the conditioning pad 45 manufactured at operation S13.

Further, method 900 includes contacting an object 15 with the surface 21 of the polishing pad 20 at operation S22. For example, a wafer 15 may be picked up and moved into contact with the polishing pad 20.

Method 900 also includes spinning the polishing pad 20 at operation S23.

In some embodiments, method 900 includes rotating the object 15 at operation S24.

Further, method 900 may include introducing a polishing agent to the surface 21 at operation S25.

Also, method 900 includes conditioning the polishing pad with the conditioning pad 45 at S26. In some embodiments, operations S23, S24, S25 and S26 may be performed simultaneously. Alternatively, operation S26 may be performed independent of the polishing process steps.

When the desired polished surface is achieved on the object, the method 900 may include removing the object from the polishing pad at operation S27.

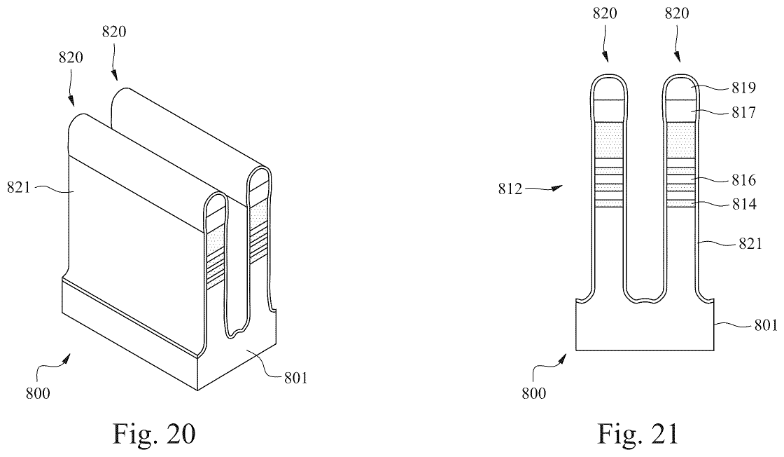

Operations S21 through S27 may be considered to represent a method for polishing a wafer. FIGS. 20-25 illustrate the use of the method for polishing as applied in a semiconductor manufacturing process, with a semiconductor structure as the object being polished.

FIG. 20 is perspective view of a semiconductor structure 800, and FIG. 21 is a cross-sectional view of the semiconductor structure 800 at the same stage of fabrication.

As shown, the structure 800 includes a substrate 801. The substrate 801 may be a silicon (Si) substrate. The substrate 801 may include various layers, including conductive or insulating layers formed on a semiconductor substrate. The substrate 801 may include various doping configurations depending on design requirements as is known in the art. For example, different doping profiles (e.g., p-well, n-well) may be formed on the substrate 801 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 801 includes a single crystalline semiconductor layer on at least its surface portion. The substrate 801 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 801 may include a compound semiconductor and/or an alloy semiconductor. In the illustrated embodiment, the substrate 801 is made of crystalline Si.

As shown, an epitaxial stack 812 is formed over the substrate 801. The epitaxial stack 812 includes epitaxial layers 814 of a first composition interposed by epitaxial layers 816 of a second composition. The first and second composition may be different. Embodiments are possible including those that provide for a first composition and a second composition having different oxidation rates and/or etch selectivity. In an embodiment, the epitaxial layers 814 are SiGe and the epitaxial layers 816 are silicon. In embodiments wherein the epitaxial layer 814 includes SiGe and the epitaxial layer 816 includes silicon, the silicon oxidation rate is less than the SiGe oxidation rate.

By way of example, epitaxial growth of the epitaxial stack 812 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 816 include the same material as the substrate 801. In some embodiments, the epitaxially grown layers 814 and 816 include a different material than the substrate 801. As stated above, in at least some examples, the epitaxial layer 814 includes an epitaxially grown Si₁₋ₓGeₓ layer (wherein x is from 0.10 to 0.55 and the epitaxial layer 816 includes an epitaxially grown silicon (Si) layer. Alternatively, in some embodiments, either of the epitaxial layers 814 and 816 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 814 and 816 may be chosen based on providing differing oxidation, etch selectivity properties. In various embodiments, the epitaxial layers 814 and 816 are substantially dopant-free (i.e., having an extrinsic dopant concentration from 0 cm⁻³ to 1×10¹⁷ cm⁻³), where for example, no intentional doping is performed during the epitaxial growth process. In some embodiments, the bottom layer and the top layer of the epitaxial stack 812 are SiGe layers. In alternative embodiments, the bottom layer of the epitaxial stack 812 is a Si layer and the top layer of the epitaxial stack 812 is a SiGe layer.

As further shown, the epitaxial stack 812 is patterned to form semiconductor fins 820. In some embodiments, a mask layer 817 over the epitaxial stack 812, as shown in FIG. 7. An exemplary mask layer 817 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. A mask layer 819 if formed over the mask layer 817. In certain embodiments, the mask layer 819 is silicon oxide. The mask layers 817 and 819 are patterned into a mask pattern by using patterning operations including photolithography and etching.

As shown, the epitaxial stack 812 is patterned in an etching process, such as a dry etch (e.g., reactive ion etching), a wet etch, and/or other suitable process, through openings defined in the patterned mask layer 817. The stacked epitaxial layers 814 and 816 are thereby patterned into the fin 820. Trenches are etched between adjacent fins 820.

As further shown in FIGS. 20 and 21, an oxide liner 821 is formed over the etched structure 800.

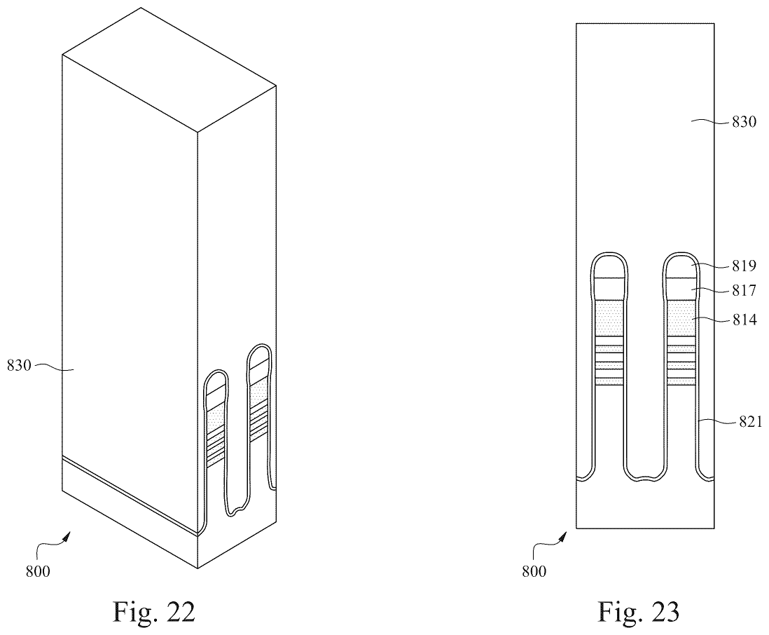

FIG. 22 is perspective view of a semiconductor structure 800, and FIG. 23 is a cross-sectional view of the semiconductor structure 800 at the same stage of fabrication.

As shown in FIGS. 22 and 23, an isolation material 830 is formed over and between the fins 820. For example the isolation material 830 may be silicon oxide. In certain embodiments, the isolation material 830 is formed by a flowable chemical vapor deposition (FCVD) process. In certain embodiments, a plasma-enhanced CVD process is performed to form an additional layer of isolation material 830.

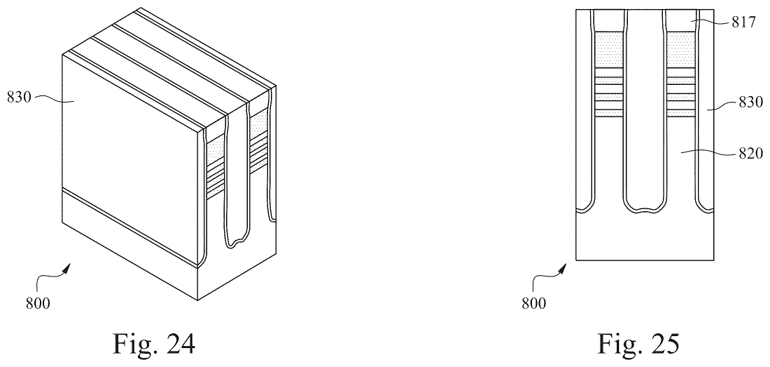

FIG. 24 is a perspective view of a semiconductor structure 800, and FIG. 25 is a cross-sectional view of the semiconductor structure 800 at the same stage of fabrication.

In FIGS. 24 and 25, the semiconductor structure 800 has been polished according to operations S21 through S27. Specifically, the semiconductor structure 800 is contacted with the polishing pad at operation S22, the method spins the polish pad at operation S23, the semiconductor structure 800 is rotated at operation S24, a polishing agent may be injected at operation S25, the polishing pad is conditioned at operation S26, and the semiconductor structure 800 is removed from the polishing pad at operation S27.

The polishing process may remove the isolation material 830 located over the fins 820 and may land on the silicon nitride mask layer 817. Further processing may recess the isolation material 830 to form shallow trench isolation between the fins 820. Any suitable etching technique may be used to recess the isolation material 830 including dry etching, wet etching, RIE, and/or other etching methods, and in an exemplary embodiment, an anisotropic dry etching is used to selectively recess the isolation material without etching the fins 820.

As described herein, a conditioning pad, methods for forming conditioning pads, and methods for polishing wafers are provided and result in better control of within wafer and within zone thickness uniformity and a reduction in CMP-induced defects.

Conditioning pads herein are provided with different structural, material and layout designs to improve within-die (WiD) and/or within-wafer (WiW) uniformity while reducing CMP-induced defects, thereby increasing polishing performance for yield and electrical property enhancement.

Use of three-dimensional printing to form the conditioning pad allows for pixel or grain level control of material hardness of the base member and projections of the conditioning pad.

In one embodiment, a pad is provided for use in semiconductor fabrication. The pad includes a base member having an upper surface; projections extending upward from the upper surface of the base member, wherein the projections are formed with an edge defined by at least two intersecting surfaces; and a diamond layer overlying the projections.

In certain embodiments, the pad is a conditioning pad for conditioning a polishing pad configured to polish a semiconductor wafer.

In certain embodiments of the pad, the diamond layer includes chemical vapor deposition (CVD) diamond.

In certain embodiments of the pad, the projections are comprised of a common material selected from acrylic, polyurethane, polyester, polyimide, carbon treated polymer, and/or combinations thereof.

In certain embodiments of the pad, a first group of projections are comprised of a first material having a first hardness and a second group of projections are comprised of a second material having a second hardness less than the first hardness.

In certain embodiments of the pad, the pad includes a first array of the projections formed at a first pitch and a second array of the projection offset from the first array.

In certain embodiments of the pad, the pad includes a first array of the projections formed at a first pitch, a second array of the projection offset from the first array, and a third array of projections offset from the first array and the second array.

In certain embodiments of the pad, the projections are confined to a first region of the base member, and wherein a second region of the base member is void of the projections.

In certain embodiments of the pad, the projections are confined to first regions of the base member, second regions of the base member are void of the projections, and the first regions and second regions are arranged in a fan pattern, concentric pattern, turbine pattern, or segmented pattern.

In another embodiment, a method for manufacturing a conditioning pad is provided. The method includes forming projections over an upper surface of a base member of the conditioning pad, wherein the projections are formed with a maximum width at a base on the upper surface of the base member and extend upward to an apex; and coating the projections with a diamond layer.

In certain embodiments of the method, coating the projections with the diamond layer includes performing a chemical vapor deposition (CVD) process to deposit the diamond layer.

In certain embodiments of the method, forming the projections over the base member of the conditioning pad includes performing a three-dimensional printing process.

In certain embodiments of the method, the three-dimensional printing process forms the base member and the projections.

In certain embodiments of the method, forming the projections over the base member of the conditioning pad includes screening a portion of the base member with a sieve to define non-screened regions of the base member and forming the projections over the non-screened regions.

In certain embodiments of the method, forming projections over the base member of the conditioning pad includes forming first projections having a first hardness and forming second projections having a second hardness less than the first hardness.

In another embodiment, a method for polishing is provided. The method includes contacting an object to a polishing surface of a polishing pad; rotating the polishing pad; and contacting a conditioning pad to the polishing surface of a polishing pad to roughen the polishing surface, wherein the conditioning pad includes projections and a diamond layer overlying the projections, and wherein the diamond layer contacts the polishing surface.

In certain embodiments of the method, the diamond layer includes chemical vapor deposition (CVD) diamond.

In certain embodiments of the method, the projections include first projections having a first hardness and second projections having a second hardness less than the first hardness.

In certain embodiments of the method, the conditioning pad includes a first array of the projections formed at a first pitch and a second array of the projection offset from the first array.

In certain embodiments of the method, the projections are confined to first regions of the conditioning pad; second regions of the conditioning pad are void of the projections; and the first regions and second regions are arranged in a fan pattern, concentric pattern, turbine pattern, or segmented pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pad for use in semiconductor fabrication, the pad comprising:
a base member having an upper surface;
projections extending upward from the upper surface of the base member, wherein the projections are formed with an edge defined by at least two intersecting surfaces; and
a diamond layer overlying the projections.

2. The pad of claim 1, wherein the pad is a conditioning pad for conditioning a polishing pad configured to polish a semiconductor wafer.

3. The pad of claim 1, wherein the diamond layer comprises chemical vapor deposition (CVD) diamond.

4. The pad of claim 1, wherein the projections are comprised of a common material selected from acrylic, polyurethane, polyester, polyimide, carbon treated polymer, and/or combinations thereof.

5. The pad of claim 1, wherein a first group of projections are comprised of a first material having a first hardness and a second group of projections are comprised of a second material having a second hardness less than the first hardness.

6. The pad of claim 1, wherein the pad comprises a first array of the projections formed at a first pitch and a second array of the projections offset from the first array.

7. The pad of claim 1, wherein the pad comprises a first array of the projections formed at a first pitch, a second array of the projections offset from the first array, and a third array of projections offset from the first array and the second array.

8. The pad of claim 1, wherein the projections are confined to a first region of the base member, and wherein a second region of the base member is void of the projections.

9. The pad of claim 1, wherein:
the projections are confined to first regions of the base member;
second regions of the base member are void of the projections; and
the first regions and the second regions are arranged in a fan pattern, concentric pattern, turbine pattern, or segmented pattern.

10. A method for manufacturing a conditioning pad, the method comprising:
forming projections over an upper surface of a base member of the conditioning pad, wherein the projections are formed with a maximum width at a base on the upper surface of the base member and extend upward to an apex; and
coating the projections with a diamond layer.

11. The method of claim 10, wherein coating the projections with the diamond layer comprises performing a chemical vapor deposition (CVD) process to deposit the diamond layer.

12. The method of claim 10, wherein forming the projections over the base member of the conditioning pad comprises performing a three-dimensional printing process.

13. The method of claim 12, wherein the three-dimensional printing process forms the base member and the projections.

14. The method of claim 10, wherein forming the projections over the base member of the conditioning pad comprises screening a portion of the base member with a sieve to define non-screened regions of the base member and forming the projections over the non-screened regions.

15. The method of claim 10, wherein forming projections over the base member of the conditioning pad comprises forming first projections having a first hardness and forming second projections having a second hardness less than the first hardness.

16. A method for polishing, the method comprising:
contacting an object to a polishing surface of a polishing pad;
rotating the polishing pad; and
contacting a conditioning pad to the polishing surface of the polishing pad to roughen the polishing surface, wherein the conditioning pad comprises projections and a diamond layer overlying the projections, and wherein the diamond layer contacts the polishing surface.

17. The method of claim 16, wherein the diamond layer comprises chemical vapor deposition (CVD) diamond.

18. The method of claim 16, wherein the projections include first projections having a first hardness and second projections having a second hardness less than the first hardness.

19. The method of claim 16, wherein the conditioning pad comprises a first array of the projections formed at a first pitch and a second array of the projections offset from the first array.

20. The method of claim 16, wherein
the projections are confined to first regions of the conditioning pad;
second regions of the conditioning pad are void of the projections; and
the first regions and the second regions are arranged in a fan pattern, concentric pattern, turbine pattern, or segmented pattern.
